(19) United States
(12) Patent Application Publication
(10) Pub. No.: US 2008/0054434 A1
(43) Pub. Date: Mar. 6, 2008

(54) SEMICONDUCTOR STACK PACKAGE FOR OPTIMAL PACKAGING OF COMPONENTS HAVING INTERCONNECTIONS

(76) Inventor: Jae Myun KIM, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/777,420

(22) Filed: Jul. 13, 2007

(30) Foreign Application Priority Data
Aug. 31, 2006 (KR) 10-2006-0083792

(51) Int. Cl. H01L 23/02

(52) U.S. Cl. 257/686; 257/E23.002

(57) ABSTRACT

A stack package comprises a first semiconductor package having a substrate which is formed with a plurality of conductive patterns on a lower surface thereof and with an insulation layer on the lower surface thereof including the conductive patterns, the insulation layer having grooves for exposing the portions of the conductive patterns disposed at least both end portions of the substrate; a second semiconductor package located below the first semiconductor package and having the same structure as the first semiconductor package; conductive adhesives formed on the exposed end portions of the conductive patterns of the first and second semiconductor packages; and a plurality of clip-shaped conductors clipped on both ends of the second semiconductor package and having first ends and second ends which electrically and mechanically connect the conductive patterns of the first semiconductor package and the conductive patterns of the second semiconductor package to each other via the conductive adhesives.

### CROSS-REFERENCE TO RELATED APPLICATIONS

The present application claims priority to Korean patent application number 10-2006-0083792 filed on Aug. 31, 2006, which is incorporated herein by reference in its entirety.

### BACKGROUND OF THE INVENTION

The present invention relates to a semiconductor package, and more particularly to a stack package, which ensures easy packaging despite problematic interconnections and insufficient interconnection spaces.

As electronic products become increasingly multi-functional light weight, slim, compact, and miniature, the high-density mounting of packages is required to facilitate such characteristics. In particular, the multi-functional nature of an electronic product necessitates an increased number of packages must be mounted on a substrate of limited size; therefore, various techniques for the high-density mounting of packages have been researched and suggested in the art. Research has also focused on decreasing the size of the package in high-density mounting.

Conventionally, a multi-chip package or multi-chip module package, realized by mounting a plurality of chips or packages having identical memory capacity, is used in high-density mounting of packages and decreasing the size of a package. However, the manufacture of a multi-chip package and multi-chip module package is limited because semiconductor chips and packages are mounted so as to be positioned on the same plane of a substrate.

In consideration of this fact, a packaging technology has been suggested in which a plurality of chips having the same memory capacity is integrally stacked upon one another. A package configured in this way is called a stack chip package. The stack chip package provides advantages in that they decrease the manufacturing cost of a package through simplified processes and can be mass-produced.

FIG. 1 is a cross-sectional view illustrating a conventional stack chip package.

Referring to FIG. 1, the conventional stack chip package is configured in a manner such that a plurality of semiconductor chips 120, 130 and 140 having different sizes are stacked on a substrate 110. The respective semiconductor chips 120, 130 and 140 are attached to the substrate 110 and the lower semiconductor chips 120 and 130 by adhesives 114, and have bonding pads 122, 132 and 142 adjacent to the edges thereof. The bonding pads 122, 132 and 142 of the semiconductor chips 120, 130 and 140 are electrically connected to the electrode terminals 112 provided on the upper surface of the substrate 110 through bonding wires 124, 134 and 144.

In order to protect the semiconductor chips 120, 130 and 140 from the external environment, the upper surface of the substrate 110 including the semiconductor chips 120, 130 and 140 and the bonding wires 124, 134 and 144 is molded using epoxy-based resin, that is, an encapsulant 150. Solder balls 160 serving as external connection terminals are attached to the ball lands (not shown) provided on the lower surface of the substrate 110.

It is difficult to design interconnections for electrically connecting at least two semiconductor chips in the conventional stack chip package, and the bonding wires are likely to be short-circuited due to insufficient interconnection spaces.

In the conventional art, packaging into a stack chip package is implemented after a probing test is performed for each semiconductor chip. A defective chip, generated during the packaging process and burn-in test, cannot be detected until the manufacture process for the stack chip package is completed and the stack package subsequently tested. Therefore, the manufacturing yield of the product decreases due to the presence of defective chips.

### SUMMARY OF THE INVENTION

An embodiment of the present invention is directed to a stack package which ensures easy packaging despite a problematic design of interconnections and insufficient interconnection spaces.

Also, another embodiment of the present invention is directed to a stack package which allows detection of a defective chip prior to implementation of the stacking process, thereby preventing a decrease in the manufacturing yield.

In one embodiment, a stack package comprises a first semiconductor package having a substrate which is formed with a plurality of conductive patterns on a lower surface thereof and with an insulation layer on the lower surface thereof including the conductive patterns, the insulation layer having grooves for exposing the portions of the conductive patterns disposed at least both end portions of the substrate; a second semiconductor package located below the first semiconductor package and having the same structure as the first semiconductor package; conductive adhesives formed on the exposed portions of the conductive patterns of the first and second semiconductor packages; and a plurality of clip-shaped conductors clipped on both ends of the second semiconductor package and having first ends and second ends which electrically and mechanically connect the conductive patterns of the first semiconductor package and the conductive patterns of the second semiconductor package to each other via the conductive adhesives.

Each of the first and second semiconductor packages comprises the substrate having a cavity defined at the middle portion thereof, the plurality of conductive patterns formed on the lower surface thereof and extending from positions adjacent to the cavity to the edges of the substrate, and the insulation layer formed on the lower surface thereof including the conductive patterns to expose the portions of the conductive patterns disposed at least both end portions and a center portion of the substrate; a center pad type semiconductor chip attached to the substrate in a face-down manner and having a plurality of bonding pads which are exposed through the cavity of the substrate; bonding wires for electrically connecting the bonding pads of the semiconductor chip and the conductive patterns of the substrate to each other through the cavity of the substrate; and an encapsulant for molding the cavity of the substrate including the bonding wires and the upper surface of the substrate including the semiconductor chip.

The grooves are defined in a line type adjacent to both edges of the lower surface of the substrate.

The insulation layer comprises a solder resist.

The conductive adhesives comprise solder pastes, solder bumps or combinations thereof.

The conductive adhesives comprise metal bumps.

The clip-shaped conductors are plated with solder on surfaces thereof.

The stack package further comprises an adhesive applied between the substrate and the semiconductor chip.

The stack package further comprises external connection terminals attached to the exposed partial areas of the conductive patterns of the first and second semiconductor packages.

The external connection terminals comprise solder balls or conductive pins.

The external connection terminals provided for the first semiconductor package have a thickness which is less than that of the external connection terminals provided for the second semiconductor package.

### BRIEF DESCRIPTION OF THE DRAWINGS

FIG. 1 is a cross-sectional view illustrating a conventional stack chip package.

FIGS. 2 and 3 are a perspective view and a cross-sectional view illustrating an FBGA type semiconductor package in accordance with a first embodiment of the present invention.

FIG. 4 is a view illustrating an apparatus for inspecting the FBGA type semiconductor package in accordance with the embodiment of the present invention for defectiveness, and explaining an inspection method.

FIG. 5 is a cross-sectional view illustrating a stack package in accordance with a second embodiment of the present invention.

FIGS. 5A and 5B are cross-sectional views explaining a method for manufacturing the stack package in accordance with the second embodiment of the present invention.

FIG. 6 is a cross-sectional view illustrating a stack package in accordance with a third embodiment of the present invention.

FIG. 7 is a cross-sectional view illustrating a stack package in accordance with a fourth embodiment of the present invention.

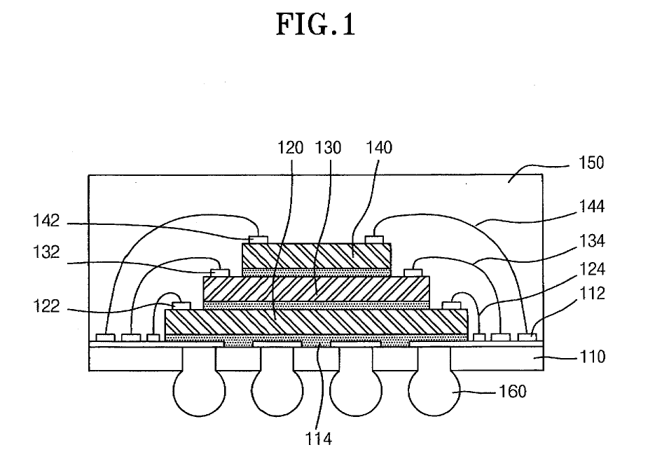

### DESCRIPTION OF SPECIFIC EMBODIMENTS

In the present invention, a single fine-pitch ball grid array (FBGA) type semiconductor package is configured in a manner such that grooves are defined adjacent to both edges of the substrate, which is formed with a plurality of conductive patterns on the lower surface thereof, to partially expose the conductive patterns. Clip-shaped conductors are clipped into the grooves, and the corresponding portions of the conductive patterns of upper and lower FBGA type semiconductor packages are connected to each other using the clip-shaped conductors clipped in this way, whereby a stack package is realized.

In this case, in the present invention, the use of clip-shaped conductors in the stack package allows for easy realization of the stack package despite insufficient interconnection spaces. Also, in the present invention, subsequent to a test performed for the semiconductor chip included in a single package to detect any defective chips, a stack package is realized using FBGA packages each having a semiconductor chip which is free from defects, thereby preventing or minimizing a decrease in manufacturing yield.

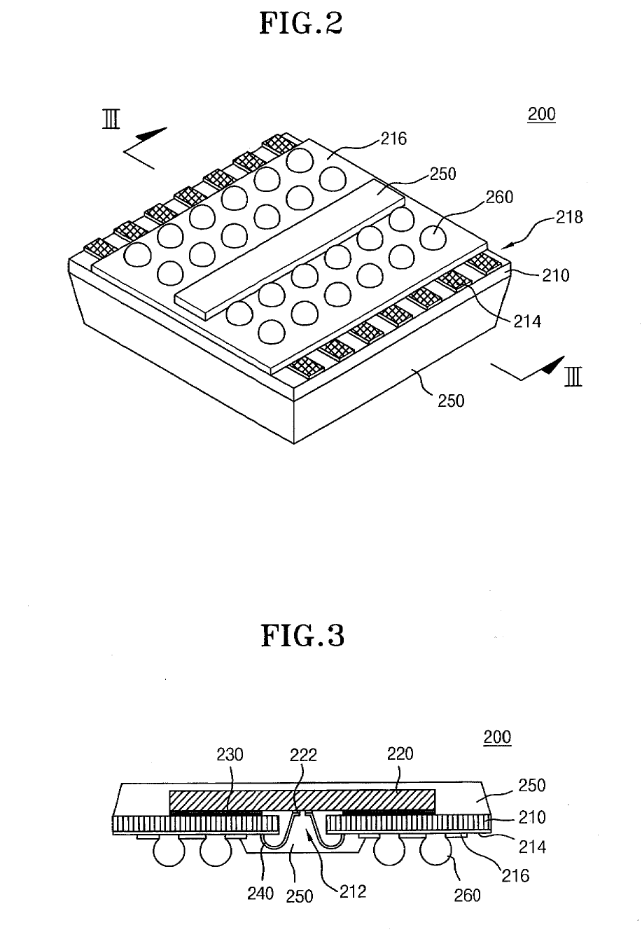

Hereafter, an FBGA type semiconductor package in accordance with a first embodiment of present invention will be described in detail with reference to FIGS. 2 and 3.

As shown in FIGS. 2 and 3, a substrate 210 has a cavity 212 located at the middle portion thereof. A plurality of conductive patterns 214 is formed on the lower surface of the substrate 210 to extend from positions adjacent to the cavity 212 to the edges of the substrate 210. An insulation layer, preferably, a solder resist 216 is formed on the lower surface of the substrate 210 including the conductive patterns 214. The solder resist 216 has grooves 218 which are defined to expose both end portions and partial areas of the conductive patterns 214. As will be described later in detail, the grooves 218 are defined to form electrical connections between individual semiconductor packages when manufacturing a stack package. Preferably, the grooves 218 are defined in a line type.

A center pad type semiconductor chip 220, which has bonding pads 222 centrally provided thereon, is attached in a face-down manner to the substrate 210 by an adhesive 230. The adhesive 230 comprises epoxy resin or polyimide-based resin, and is applied in a thickness of about 25 μm to the junction surface of any portions of the semiconductor chip 220 and substrate 210 which are joined with each other. The bonding pads 222 of the semiconductor chip 220 and the conductive patterns 214 of the substrate 210 are electrically connected to each other by bonding wires 240 which pass through the cavity 212 of the substrate 210.

The cavity 212 of the substrate 210 including the bonding wires 240 and the upper surface of the substrate 210 including the semiconductor chip 220 are molded by an encapsulant 250. Solder balls or conductive pins, for example, solder balls 260 serving as external connection terminals are respectively attached to the exposed areas of the conductive patterns 214, as a result of which a single FBGA type semiconductor package 200 is completely configured.

In the FBGA type semiconductor package 200 according to the present invention, since the grooves 218 are defined such that they are adjacent to opposing edges on the lower surface of the substrate 210, both end portions of the conductive patterns 214, which are placed adjacent to the edges of the substrate 210, are exposed such that stacking of the FBGA type semiconductor package 200 can be easily implemented even in a narrow space.

The FBGA type semiconductor package in accordance with the first embodiment of the present invention is manufactured as described below.

First, the substrate 210 is prepared, in which the substrate has the cavity 212 located at the middle portion thereof, is formed with the conductive patterns 214 on the lower surface thereof and with the solder resist 216 to expose both end portions and the partial areas of the conductive patterns 214. The center pad type semiconductor chip 220 is attached in a face-down manner to the upper surface of the substrate 210 with adhesive 230.

Then, the bonding pads 222 of the semiconductor chip 220 and the conductive patterns 214 of the substrate 210 are electrically connected to each other through bonding wires 240 which pass through the cavity 212 of the substrate 210.

Next, the cavity 212 of the substrate 210 including the bonding wires 240 and the upper surface of the substrate 210 including the semiconductor chip 220 are molded by the encapsulant 250.

Thereafter, the solder balls 260 serving as external connection terminals are respectively attached to the partial areas of the conductive patterns 214 which are exposed on the lower surface of the substrate 210. As a result, the FBGA type semiconductor package 200, in which both end portions of the conductive patterns 214 are exposed to allow the FBGA type semiconductor package 200 to be easily stacked, is completed.

Meanwhile, in the present invention, before forming a stack package, the manufactured single FBGA type semiconductor package is tested, as described below, to detect any defective chips.

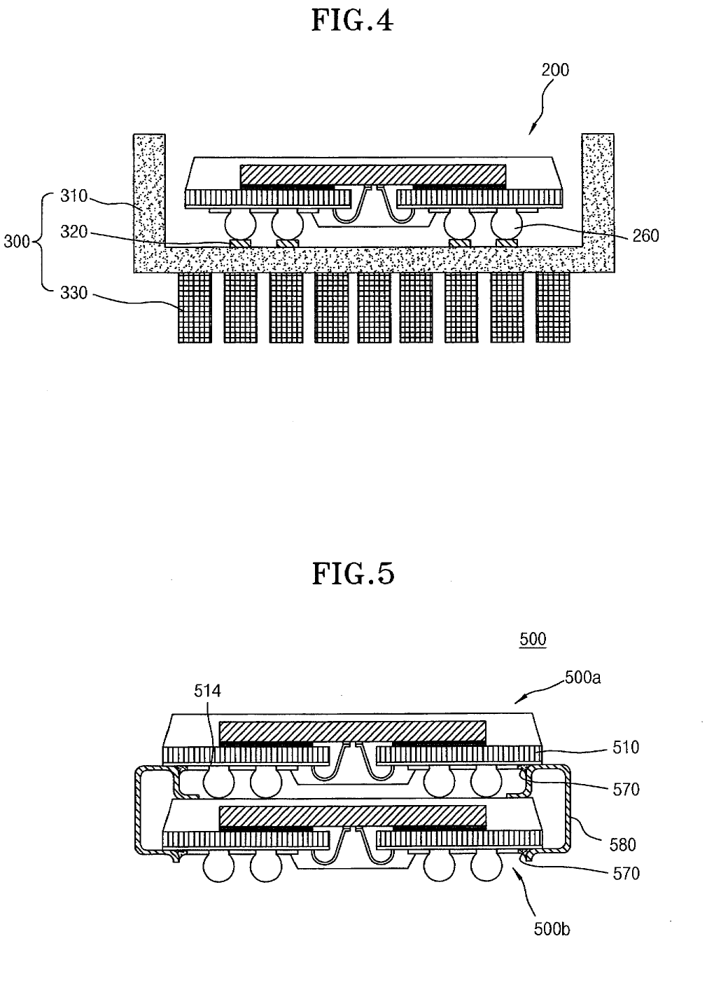

FIG. 4 is a view illustrating an apparatus for testing the FBGA type semiconductor package in accordance with the embodiment of the present invention for defective chips, and explaining an inspection method.

Referring to FIG. 4, a defect inspection apparatus 300 has a test socket 310 in which the single FBGA type semiconductor package 200 is received. The test socket 310 has a shape which is opened at an upper end thereof. A plurality of contact pins 320, to be brought into one to one contact with the solder balls 260 of the FBGA type semiconductor package 200, are provided on the inner bottom surface of the test socket 310. A plurality of signal probe pins 330, which are connected to test circuits, are provided on the outer bottom surface of the test socket 310.

The contact pins 320, which are provided on the inner bottom surface of the test socket 310, are made with hooks or rings having an elastic property or springs, and are electrically brought into contact with the solder balls 260 of the FBGA type semiconductor package 200 by virtue of a mechanical elastic force.

The testing of the FBGA type semiconductor package using the defect inspection apparatus is performed in a manner such that, after a burn-in test is performed with the FBGA type semiconductor package presently located in the test socket 310 prior to stacking of the FBGA type semiconductor package, whether the semiconductor package has a defective chip is determined based on the electrical signals received from the signal probe pins 330. Then, FBGA type semiconductor packages free of defective chips, which are identified through the test, are collected and used in the manufacture of a stack package.

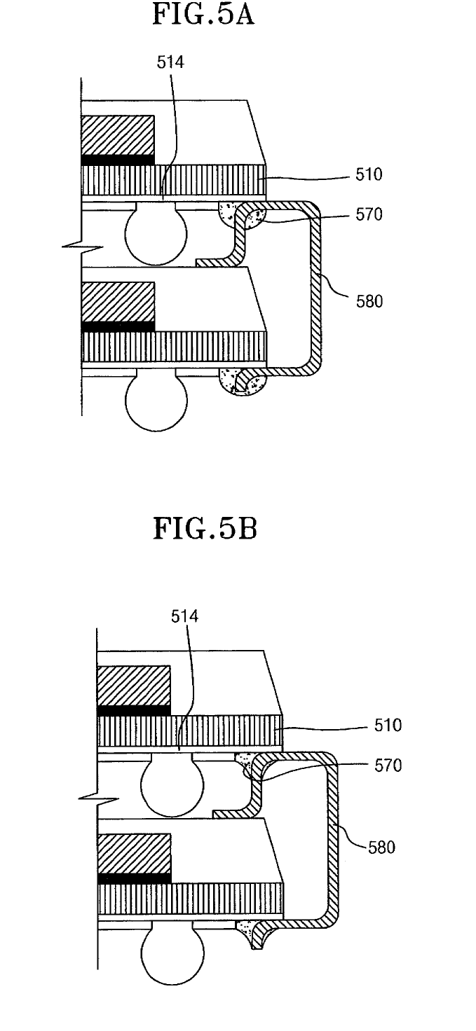

FIG. 5 is a cross-sectional view illustrating a stack package in accordance with a second embodiment of the present invention.

As shown in the drawing, a stack package 500 has a structure in which first and second FBGA type semiconductor packages 500a and 500b having the same structure as shown in FIG. 3 and determined to lack defective chips through the above-described test are stacked one upon the other.

Solder pastes 570 serving as conductive adhesives are formed on the exposed end portions of the conductive patterns 514 of the first semiconductor package 500a located upward and on the exposed end portions of the conductive patterns 514 of the second semiconductor package 500b located downward. Clip-shaped conductors 580 are clipped onto the edge portions of the substrate 510 of the downwardly located second semiconductor package 500b. One end of each clip-shaped conductor 580 is connected to the exposed end portions of the conductive patterns 514 of the second semiconductor package 500b, and the other end of each clip-shaped conductor 580 is connected to the exposed end portions of the conductive patterns 514 of the first semiconductor package 500a.

A method for manufacturing the stack package in accordance with the second embodiment of the present invention will be described below.

Referring to FIG. 5A, the first semiconductor package 500a and the second semiconductor package 500b, which are proved to be non-defective, are prepared, and the solder pastes 570 are formed on the end portions of the conductive patterns 514 which are exposed on the lower surfaces of the substrates 510 of the respective first and second semiconductor packages 500a and 500b. The clip-shaped conductors 580 are clipped onto the end portions of the substrate 510 of the downwardly located second semiconductor package 500b. At this time, one end of each clip-shaped conductor 580 is connected to the end portions of the conductive patterns 514 which are exposed on the lower surface of the substrate 510 of the second semiconductor package 500b.

Next, the first semiconductor package 500a is positioned on the second semiconductor package 500b which has the clip-shaped conductors 580 installed on both end portions thereof. The first semiconductor package 500a is positioned in a manner such that the end portions of the conductive patterns 514, which are exposed on the lower surface of the substrate 510 of the first semiconductor package 500a, are brought into contact with the other ends of the clip-shaped conductors 580.

Referring to FIG. 5B, a reflow process is conducted in a manner such that the clip-shaped conductors 580 and the semiconductor packages 500a and 500b are electrically connected to and physically fastened to each other by the solder pastes 570, whereby the stack package 500 is completed.

In the stack package in accordance with the second embodiment of the present invention, constructed as described above, since the semiconductor packages are stacked using the clip-shaped conductors 580, the packages can be easily stacked in spite of insufficient interconnection spaces. Also, in the present invention, because a single package is tested to guarantee it does not contain any defective chips prior to manufacturing the stack package, thereby ensuring only non-defective packages are used in the stack package manufacturing process, it is possible to prevent decreases in the manufacturing yield.

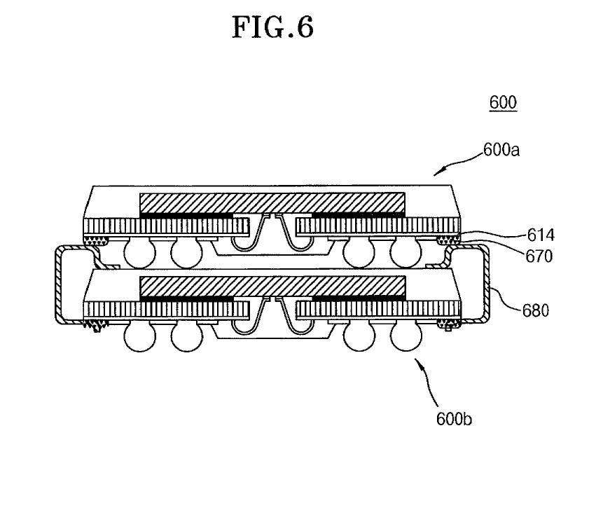

FIG. 6 is a cross-sectional view illustrating a stack package in accordance with a third embodiment of the present invention.

Referring to FIG. 6, in a stack package 600 in accordance with a third embodiment of the present invention, instead of the solder pastes, solder bumps 670 serving as conductive adhesives are formed on the exposed end portions of conductive patterns 614. By conducting a reflow process, clip-shaped conductors 680 and semiconductor packages 600a and 600b are electrically and mechanically connected to each other by the solder bumps 670.

Since the remaining component elements of the stack package in accordance with the third embodiment of the present invention, excluding the solder bumps 670, are the same as those of the aforementioned first embodiment, a detailed description thereof will be omitted herein.

As the conductive adhesives, combinations of solder pastes and solder bumps can be used in place of the solder bumps 670 which are made of single material.

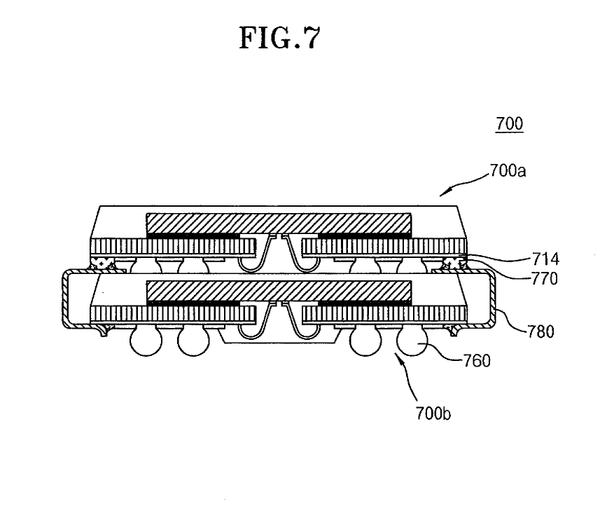

FIG. 7 is a cross-sectional view illustrating a stack package in accordance with a fourth embodiment of the present invention.

Referring to FIG. 7, in a stack package 700 in accordance with a fourth embodiment of the present invention, a predetermined thickness of each solder ball 760 of a first semiconductor package 700a located upward is removed, metal bumps 770 serving as conductive adhesives are formed in place of the solder pastes and the solder bumps on the exposed end portions of conductive patterns 714, and clip-shaped conductors 780 which are plated with solder are employed.

After the first semiconductor package 700a formed with the metal bumps and a second semiconductor package 700b are stacked using the clip-shaped conductors, by conducting a reflow process employing an ultraviolet lamp or the like, as the plating layers plated on the clip-shaped conductors 780 are melted, the clip-shaped conductors 780 and the metal bumps 770 are fused with each other, thereby electrically and mechanically connecting the clip-shaped conductors 780 and the first and second semiconductor packages 700a and 700b to each other.

The solder balls 760 of the first semiconductor package 700a have a thickness which is less than that of the solder balls 760 of the second semiconductor package 700b. For example, the predetermined thickness of the solder ball 760 of the first semiconductor package 700a is removed such that the thickness of remaining solder ball 760 of the first semiconductor package 700a corresponds to the combined thickness of the metal bump 770 formed on the exposed end portions of the conductive patterns 714 and the clip-shaped conductor 780 plated with the solder. Unlike those of the aforementioned embodiments, the other ends of the clip-shaped conductors 780 plated with the solder, which are brought into contact with the conductive patterns 714 of the first semiconductor package 700a, are partially changed in their shapes. Preferably, the other ends of the clip-shaped conductors 780 are formed to have a shape which is not up-set or down-set only to allow each clip-shaped conductor 780 to be clipped onto the second semiconductor package 700b.

Since the remaining component elements of the stack package in accordance with the fourth embodiment of the present invention are the same as those of the aforementioned embodiments, detailed description thereof will be omitted herein.

The stack package in accordance with the fourth embodiment may be configured in a manner such that metal bumps are applied only to the first semiconductor package, rather than both first and second semiconductor packages, and solder pastes are applied to the second semiconductor package. Moreover, the solder pastes can be added to the metal bumps and used together.

As is apparent from the above description, in the present invention, FBGA type semiconductor packages are electrically connected using clip-shaped conductors. Therefore, since the semiconductor packages can be electrically connected even in a narrow space, insufficient space no longer poses a problem as in the conventional art. In particular, because the clip-shaped conductors are used to electrically connect the semiconductors, it is possible to provide an interconnection design allowing semiconductor packages to be electrically connected even in a narrow space. As a consequence, it is possible to realize a stack package which is light, slim, compact and miniature and has increased degree of integration.

Further, in the present invention, since chips are inspected to ensure they are not defective prior to conducting the stacking process, reduction in the manufacturing yield due to the presence of a defective chip can be prevented, and the reliability of a stack package can be improved.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A stack package comprising:
a first semiconductor package having a substrate formed with a plurality of conductive patterns on a lower surface of the substrate and formed with an insulation layer on the lower surface of the substrate formed with the conductive patterns, the insulation layer having grooves exposing the portions of the conductive patterns disposed at least both end portions of the substrate;
a second semiconductor package located below the first semiconductor package and having the same structure as the first semiconductor package;
conductive adhesives formed on the exposed portions of the conductive patterns of the first and second semiconductor packages; and
a plurality of clip-shaped conductors clipped on both ends of the second semiconductor package and having first ends and second ends which electrically and mechanically connect the conductive patterns of the first semiconductor package and the conductive patterns of the second semiconductor package to each other via the conductive adhesives.

2. The stack package according to claim 1, wherein the substrate in each of the first and second semiconductor packages has a cavity defined at a middle portion thereof such that the plurality of conductive patterns are formed on the lower surface of the substrate to extend from positions adjacent to the cavity to edges of the substrate, and wherein the insulation layer in each of the first and second semiconductor packages is formed on the lower surface of the substrate formed with the conductive patterns to expose the portions of the conductive patterns disposed at least both end portions and a center portion of the substrate.

3. The stack package according to claim 2, wherein each of the first and second semiconductor packages comprises:
a center pad type semiconductor chip having a plurality of bonding pads attached to the substrate, wherein the plurality of bonding pads are exposed through the cavity of the substrate;
bonding wires for electrically connecting the bonding pads of the semiconductor chip and the conductive patterns of the substrate to each other through the cavity of the substrate; and
an encapsulant for molding the cavity of the substrate including the bonding wires and an upper surface of the substrate including the semiconductor chip.

4. The stack package according to claim 1, wherein the grooves of the insulation layer are linearly elongated to expose the portions of the conductive patterns disposed at least both end portions of the substrate.

5. The stack package according to claim 1, wherein the insulation layer comprises a solder resist.

6. The stack package according to claim 1, wherein the conductive adhesives made from any one of solder pastes, solder bumps, combinations of solder bumps and solder pastes, and metal bumps.

7. The stack package according to claim 1, wherein the clip-shaped conductors are plated with solder on surfaces thereof.

8. The stack package according to claim 3 further comprising:
an adhesive applied between the substrate and the semiconductor chip.

9. The stack package according to claim 3, further comprising:
external connection terminals attached to the exposed center portions of the conductive patterns of the first and second semiconductor packages.

10. The stack package according to claim 9, wherein the external connection terminals comprise solder balls or conductive pins.

11. The stack package according to claim 11, wherein the external connection terminals provided to the first semiconductor package have a thickness which is less than that of the external connection terminals provided to the second semiconductor package.
